(19) United States
(12) Patent Application Publication
(10) Pub. No.: US 2006/0027396 A1
(43) Pub. Date: Feb. 9, 2006

(54) Hot bar soldering method for soldering two circuit boards together

(75) Inventor: Yu-Jun Yang, Shenzhen (CN)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/199,311

(22) Filed: Aug. 8, 2005

(30) Foreign Application Priority Data
Aug. 6, 2004 (TW) 93123610

(51) Int. Cl. H05K 1/11

(52) U.S. Cl. 174/261; 29/830

(57) ABSTRACT

The present invention relates to a hot bar soldering method for soldering two circuit boards, including following steps: firstly, providing a first circuit board (4) including a plurality of first pads (42) and a second circuit board (5) including a plurality of second pads (52), each of the pads having opposite first and second ends, and the first pads being longer than the second pads; secondly, aligning each of the first pads and the corresponding second pads, and leaving the first ends (421) of the first pads uncovered by the second circuit board; finally, hot pressing the second circuit board where the first pads and the second pads overlap and simultaneously at the second ends of the first pads.

### BACKGROUND OF THE INVENTION

1. Field of the Invention

The present invention relates to a method for soldering two circuit boards together, and more particularly for soldering a Printed Circuit Board (PCB) and a Flexible Printed Circuit Board (“FPC”) together.

2. Description of the Related Art

A typical method for assembling a display module includes a step for electrically connecting a liquid crystal display (LCD) panel, a backlight, a driving integrate circuit (IC), a PCB, and an FPC.

Conventionally, in the step for connecting a display module, the FPC including a plurality of pads thereon is used to electrically connect the PCB including a plurality of pads thereon and the LCD panel including a plurality of leads thereon. There are two methods for connecting the FPC and the PCB. The first method is a hot bar soldering method, in which Sn/Pb solder usually having a composition of 63% tin (Sn) and 37% lead (Pb) is used. The second method is a hot-air soldering method.

As shown in FIG. 5, a typical PCB 1 includes a substrate 11 and a plurality of first pads 12 on the substrate 11. The first pads 12 are made of solder, such as Sn or Sn/Pb solder, which can be easily melted at high temperatures.

As shown in FIG. 6, a typical FPC 2 includes a flex substrate 21 and a plurality of second pads 22 on one end 211 of the flex substrate 21. The second pads 22 are made of solder, such as Sn or Sn/Pb solder, which can be easily melted at high temperatures. The second pads 22 of the flex substrate 21 are respectively connected to the first pads 12 of PCB 1. An opposite end 212 of the flex substrate 21 is connected to a plurality of leads of an LCD panel.

A typical hot bar soldering method for connecting the FPC 2 and the PCB 1 is illustrated in FIG. 7 and FIG. 8. Firstly, the first pads 12 of the PCB 1 are aligned with the corresponding second pads 22 of the FPC 2. The first pads 12 of the PCB 1 are completely covered by the FPC 2. Secondly, a hot bar 3 is moved perpendicularly toward the FPC 2 until the hot bar 3 contacts and hot presses the FPC 2 where the first pads 12 and the second pads 22 overlap. The first pads 12 and the second pads 22, which are made of solder, then melt when a high temperature is reached. After cooling down, the first pads 12 of the PCB 1 and the second pads 22 of the FPC 2 are firmly electrically connected together.

When the first pads 12 and the second pads 22 melt at high temperature in the hot pressing process, the solder of the first pads 12 expands. Because the first pads 12 are completely covered by the FPC 2, the melted first pads 12 are liable to expand laterally and form one or more short circuits 13. Furthermore, the hot bar 3 only hot presses where the first pads 12 and the second pads 22 overlap. A region L6 from a side 31 of the hot bar 3 to ends 122 of the first pads 12 is not hot pressed by the hot bar 3. In the region L6, the melted first pads 12 are liable to expand laterally and form one or more short circuits 14. In cases where a pitch of the first pads 12 and the second pads 22 is small, numerous short circuits 13, 14 may be formed in the hot pressing process. Any one or more of such short circuits may cause the display module to malfunction or even fail.

It is desired to provide an improved hot bar soldering method for connecting an FPC and a PCB, which method overcomes the above-described deficiencies.

### SUMMARY OF THE INVENTION

A method in accordance with one preferred embodiment of the present invention for soldering two circuit boards, includes the following steps: firstly, providing a first circuit board including a plurality of first pads and a second circuit board including a plurality of second pads, each of the pads having opposite first and second ends, and the first pads being longer than the second pads; secondly, aligning each of the first pads and the corresponding second pads, and leaving the first ends of the first pads uncovered by the second circuit board; finally, hot pressing the second circuit board where the first pads and the second pads overlap and simultaneously at the second ends of the first pads.

An end of the first pads is uncovered by the second circuit board, the first pads which are made of solder can freely extend to be a globoid when it melt in adequate high temperature in the hot pressing process. So that it is not easy to form a short circuit between the adjacent first pads at the first end. Further more, the melted solder produced in the hot pressing process at the second end of the first pads of the first circuit board can't assemble and form a short circuit.

Other advantages and novel features will become more apparent from the following detailed description when taken in conjunction with the accompanying drawings, in which:

### BRIEF DESCRIPTION OF THE DRAWINGS

FIG. 1 is a schematic, top plan view of one stage in connecting an FPC and a PCB using a hot bar soldering method in accordance with a first embodiment of the present invention, showing portions of pads of the FPC and PCB in dashed lines;

FIG. 2 is a side plan view of the FPC, the PCB, and the hot bar of FIG. 1;

FIG. 3 is a schematic, side plan view of one stage in connecting an FPC and a PCB using a hot bar soldering method in accordance with a second embodiment of the present invention;

FIG. 4 is a schematic, side plan view of one stage in connecting an FPC and a PCB using a hot bar soldering method in accordance with a third embodiment of the present invention;

FIG. 5 is a schematic, top plan view of a typical PCB;

FIG. 6 is a schematic, top plan view of a typical FPC;

FIG. 7 is a schematic, top plan view of one stage in connecting the FPC of FIG. 5 and the PCB of FIG. 6 using a conventional hot bar soldering method, showing portions of pads of the FPC and PCB in dashed lines; and

FIG. 8 is a side plan view of the FPC, the PCB, and the hot bar of FIG 7.

### DETAILED DESCRIPTION OF THE PRESENT INVENTION

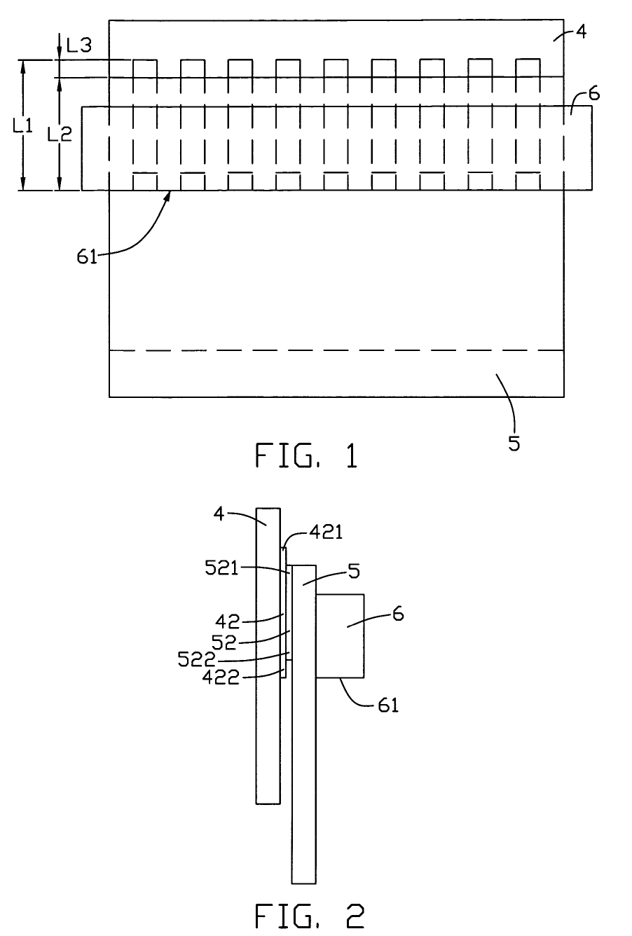

Referring to FIG. 1 and FIG. 2 together, a hot bar soldering method for connecting a PCB and an FPC according to the first embodiment of the present invention includes the following steps:

Firstly, providing a PCB 4 including a plurality of first pads 42, and an FPC 5 including a plurality of second pads 52. The first pads 42 each include a first end 421 and a second end 422, and the second pads 52 each include a first end 521 and a second end 522. A length L1 of the first pads 42 is greater than a length L2 of the second pads 52. It is preferred that a length L3 of the first pads 42 uncovered by the FPC 5 is greater than one eighth of the length L1. The pads 42, 52 are made of solder, for example Sn or Sn/Pb solder, which can be easily melted at high temperatures.

Secondly, aligning the first pads 42 of the PCB 4 and the corresponding second pads 52 of the FPC 5, and covering parts of the first pads 42 with the second pads 52, thereby leaving the first ends 421 of the first pads 42 uncovered by the FPC 5.

Finally, hot pressing the FPC 5 where the first pads 42 and the second pads 52 overlap, and simultaneously at the second ends 422 of the first pads 42. Such hot pressing is performed using a hot bar 6 having a width W. A side 61 of the hot bar 6 is aligned with the second ends 422 of the PCB 4.

Unlike in a conventional hot bar soldering method for connecting an FPC and a PCB, in the first embodiment of the present invention, the first ends 421 of the first pads 42 are exposed out of the FPC 5. Thus when the solder of the first pads 42 melts and expands, the melted solder can freely extend out beyond the FPC 5 and form enlarged globules. Thus the melted solder is less liable to expand laterally and form short circuits between adjacent first pads 42 at the first ends 421. Furthermore, the hot bar 6 simultaneously hot presses not only where the first pads 42 and the second pads 52 overlap, but also at the second ends 422 of the first pads 42. This means that the solder of the second ends 422 melts at substantially the same rate and time as the solder of other parts of the first pads 42. Therefore when the melted solder of the first ends 421 extends out beyond the FPC 5 and forms the globules, the melted solder of the second ends 422 is readily drawn and flows toward the first ends 421. Thus the melted solder of the second ends 422 is less liable to expand laterally and form short circuits between adjacent first pads 42 at the second ends 422.

FIG. 3 is a schematic, side plan view of one stage in connecting an FPC and a PCB using a hot bar soldering method in accordance with the second embodiment of the present invention. The method is similar to the first embodiment, except that a side 61′ of the hot bar 6′ extends beyond second ends 422′ of first pads 42′ of a PCB 4′ a distance L4.

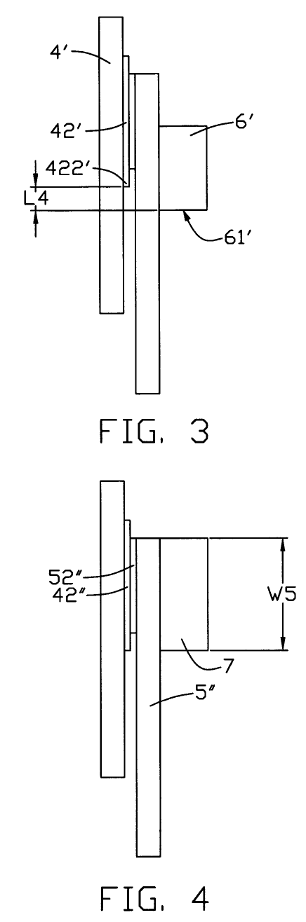

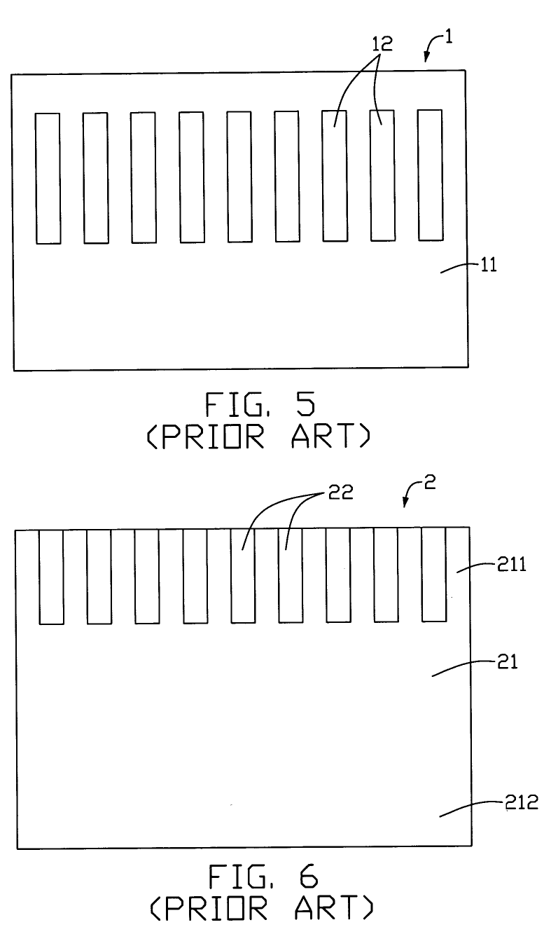

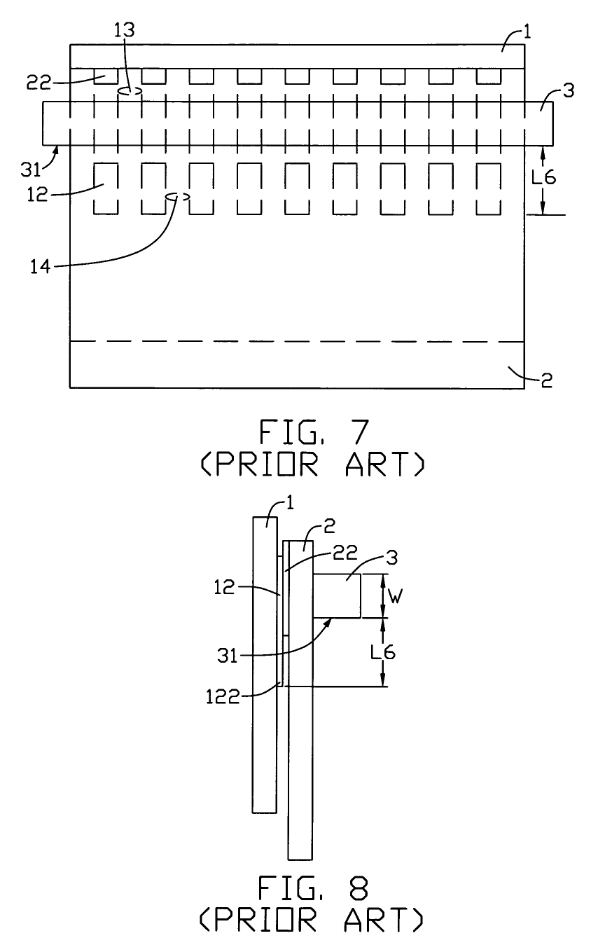

Referring to FIG. 4, a hot bar 7 is used in a hot bar soldering method in accordance with the third embodiment of the present invention. The hot bar 7 is wider than the hot bars 6 and 6′ of the first and second embodiments. The hot bar 7 completely spans a region where first pads 42″ and second pads 52″ overlap. A width W5 of the hot bar 7 is equal to or less than a length of the first pads 42″ that is covered by an FPC 5″.

It is to be understood, however, that even though numerous characteristics and advantages of the preferred embodiments have been set out in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A hot bar soldering method for soldering two circuit boards together, comprising the following steps:
providing a first circuit board including a plurality of first pads and a second circuit board including a plurality of second pads, each of the pads having opposite first and second ends, and the first pads being longer than the second pads;
aligning each of the first pads and corresponding second pads, and leaving the first ends of the first pads uncovered by the second circuit board;
hot pressing the second circuit board where the first pads and the second pads overlap and simultaneously at the second ends of the first pads.

2. The hot bar soldering method as claimed in claim 1, wherein the first circuit board is a Printed Circuit Board (PCB).

3. The hot bar soldering method as claimed in claim 1, wherein the second circuit board is a Flexible Printed Circuit Board (FPC).

4. The hot bar soldering method as claimed in claim 1, wherein a length of the first ends of the first pads uncovered by the second circuit board is greater than one-eighth of a length of the first pads.

5. The hot bar soldering method as claimed in claim 1, wherein the step of hot pressing the second circuit board includes providing a hot bar for such hot pressing.

6. The hot bar soldering method as claimed in claim 5, wherein a side of the hot bar is coextensive with the second ends of the first pads.

7. The hot bar soldering method as claimed in claim 5, wherein a width of the hot bar is equal to or less than a length of the first pads covered by the second circuit board.

8. The hot bar soldering method as claimed in claim 1, wherein the pads comprise Sn.

9. The hot bar soldering method as claimed in claim 1, wherein the pads comprise Sn/Pb solder.

10. A board assembly comprising:
a first board defining a plurality of first pads on a first surface, each of said first pads extending along a first direction with opposite first and second ends thereof;
a second board defining a plurality of second pads on the second surface intimately positioned with regard to the first surface in a parallel relation, each of said second pads extending along said first direction with opposite third and fourth ends thereof;
the first pads and the second pads of a same pitch arrangement and being aligned, engaged and overlapped with each other, respectively, in said first direction; and
a hot bar positioned on a surface of the second board opposite to the second surface and at least partially overlapped with the second pads; wherein
the first and second ends are both located outside of the third and fourth ends, respectively.

11. A board assembly comprising:
a first board defining a plurality of first pads on a first surface, each of said first pads extending along a first direction with opposite first and second ends thereof;
a second board defining a plurality of second pads on the second surface intimately positioned with regard to the first surface in a parallel relation, each of said second pads extending along said first direction with opposite third and fourth ends thereof;
the first pads and the second pads of a same pitch arrangement and being aligned, engaged and overlapped with each other, respectively, in said first direction; and
a hot bar positioned on a surface of the second board opposite to the second surface and at least partially overlapped with the second pads; wherein
a longitudinal edge of the hot bar, which extends along a second direction perpendicular to said first direction, is located either flush with or beyond the corresponding ends of the first pads in said first direction.
